(19) United States
(12) Patent Application Publication
(10) Pub. No.: US 2022/0238625 A1
(43) Pub. Date: Jul. 28, 2022

(54) DISPLAYING BASE PLATE AND DISPLAY PANEL

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Lin Zhang, Beijing (CN); Demao Yuan, Beijing (CN); Yunhao Zhang, Beijing (CN); Xiaodong Yang, Beijing (CN); Junjiao Chen, Beijing (CN); Chengguo An, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 17/478,039

(22) Filed: Sep. 17, 2021

(30) Foreign Application Priority Data
Jan. 22, 2021 (CN) 202110090199.1

(51) Int. Cl. H01L 27/32; H01L 51/52

(52) U.S. Cl. CPC H01L 27/3276; H01L 51/5253

(57) ABSTRACT

A displaying base plate includes a displaying region and a non-displaying region; the non-displaying region includes a substrate, and a first wiring unit, a first planarization part, at least one blocking wall, a second planarization part and a packaging layer located on the substrate; the first wiring unit is provided with a slot; the first planarization part and the blocking wall are provided on one side of the first wiring unit further away from the substrate; the first planarization part is closer to the displaying region than the blocking wall; orthographic projections of the first planarization part on the substrate and the blocking wall on the substrate do not intersect or overlap; the second planarization part is configured to at least fill and level up the slot in the first wiring unit that is located at the region between the first planarization part and the blocking wall.

The application claims priority to Chinese Patent Application No. 202110090199.1, titled “DISPLAYING BASE PLATE AND DISPLAY PANEL” and filed to the State Patent Intellectual Property Office on Jan. 22, 2021, the contents of which are incorporated herein by reference in its entirety.

### TECHNICAL FIELD

The present disclosure relates to the technical field of displaying, and particularly relates to a displaying base plate and a display panel.

### BACKGROUND

The luminescence unit of OLED (Organic Light Emitting Diode) display devices is formed by multiple layers of organic substances. In order to avoid organic substances suffering from erosion by water and oxygen, it is of vital importance to realize effective blocking of water and oxygen by using the packaging process.

### SUMMARY

The embodiments of the present disclosure provide a displaying base plate and a display panel.

The embodiments of the present disclosure employ the following technical solutions:

in an aspect, there is provided a displaying base plate, wherein the displaying base plate comprises a displaying region and a non-displaying region surrounding the displaying region;

the non-displaying region comprises a substrate, and a first wiring unit, a first planarization part, at least one blocking wall, a second planarization part and a packaging layer that are located on the substrate;

the first wiring unit is provided with a slot;

the first planarization part and the blocking wall are provided on one side of the first wiring unit further away from the substrate;

the first planarization part is closer to the displaying region than the blocking wall, and an orthographic projection of the first planarization part on the substrate and an orthographic projection of the blocking wall on the substrate do not intersect or overlap with each other;

the second planarization part is at least located at a region between the first planarization part and the blocking wall, and is configured to at least fill and level up the slot in the first wiring unit that is located at the region between the first planarization part and the blocking wall; and

the packaging layer covers the first planarization part, the blocking wall and the second planarization part.

Optionally, the first wiring unit comprises a first wiring layer and a second wiring layer, the first wiring layer and the second wiring layer are provided in stack, and the second wiring layer is provided on one side of the first wiring layer further away from the substrate;

the first planarization part and the blocking wall are provided on one side of the second wiring layer that is further away from the first wiring layer; and

the first wiring layer comprises a plurality of first wirings, the second wiring layer comprises a plurality of second wirings, orthographic projections of the plurality of first wirings on the substrate and orthographic projections of the plurality of second wirings on the substrate are arranged in stagger, and slots are provided between the first wirings and the second wirings.

Optionally, the first wiring unit further comprises an insulating layer, the insulating layer is located between the first wiring layer and the second wiring layer, and the insulating layer covers the plurality of first wirings.

Optionally, the second planarization part is not connected to the first planarization part and the blocking wall.

Optionally, an orthographic projection of the second planarization part on the substrate and the orthographic projection of the first planarization part on the substrate partially overlap.

Optionally, the non-displaying region comprises a plurality of the blocking walls, and the second planarization part is further configured to fill and level up the slot in the first wiring unit that is located at the region located between two neighboring instances of the blocking walls.

Optionally, the second planarization part is further configured to fill and level up the slot in the first wiring unit located at the region where the blocking wall is located.

Optionally, orthographic projections of the plurality of the blocking walls on the substrate are located within an orthographic projection of the second planarization part on the substrate.

Optionally, the width of the second planarization part ranges from 120 μm to 200 μm.

Optionally, the non-displaying region further comprises a second wiring unit, the second wiring unit is provided on one side of the second planarization part further away from the substrate, and the first planarization part and the blocking wall are provided on one side of the second wiring unit further away from the substrate.

Optionally, the first wiring unit comprises a second wiring layer, and the second wiring layer comprises a plurality of second wirings; and

the second wiring unit comprises a plurality of third wirings arranged in parallel, the orthographic projections of the third wirings on the substrate and the orthographic projections of the plurality of second wirings on the substrate intersect.

Optionally, the non-displaying region further comprises an inter-layer-medium layer, and the inter-layer-medium layer is located between the second wiring unit and the second planarization part.

Optionally, the blocking wall surrounds the displaying region, and the packaging layer extends over and covers the displaying region; and

the non-displaying region further comprises a bonding region, and a region where the second planarization part is located and the bonding region are located on a same side of the displaying region.

Optionally, the non-displaying region further comprises a fanout region, the region where the second planarization part is located is located between the displaying region and the fanout region, and partially overlaps with the fanout region.

Optionally, the packaging layer comprises a first inorganic packaging layer, an organic packaging layer and a second inorganic packaging layer provided in stack; and

the first inorganic packaging layer is located at one side of the second inorganic packaging layer closer to the second planarization part.

Optionally, the non-displaying region comprises an isolating layer and a buffer layer, and the isolating layer and the buffer layer are provided sequentially in stack between the substrate and the first wiring unit.

An embodiment of the present disclosure further provides a display panel, wherein the display panel comprises the displaying base plate stated above.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present application are provided below.

### BRIEF DESCRIPTION OF THE DRAWINGS

In order to more clearly illustrate the technical solutions of the embodiments of the present disclosure or the prior art, the figures that are required to describe the embodiments or the prior art will be briefly introduced below. Apparently, the figures that are described below are merely embodiments of the present disclosure, and a person skilled in the art can obtain other figures according to these figures without paying creative work.

FIG. 1 is a schematic structural diagram of the displaying base plate according to an embodiment of the present disclosure;

FIG. 2 is a schematic structural diagram of the displaying base plate according to another embodiment of the present disclosure;

FIG. 3 is an enlarged view of the region A defined by the dotted line in FIG. 2; and

FIG. 4 is a schematic cross-sectional view in the direction CD in FIG. 2.

### DETAILED DESCRIPTION

The technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the embodiments of the present disclosure, terms such as “first” and “second” are used to distinguish identical items or similar items that have substantially the same functions and effects, merely in order to clearly describe the technical solutions of the embodiments of the present disclosure, and should not be construed as indicating or implying the degrees of importance or implicitly indicating the quantity of the specified technical features.

In the embodiments of the present disclosure, the meaning of “plurality of” is “two or more”, and the meaning of “at least one” is “one or more”, unless explicitly and particularly defined otherwise.

In the embodiments of the present disclosure, the terms that indicate orientation or position relations, such as “upper” and “lower”, are based on the orientation or position relations shown in the drawings, and are merely for conveniently describing the present disclosure and simplifying the description, rather than indicating or implying that the device or element must have the specific orientation and be constructed and operated according to the specific orientation. Therefore, they should not be construed as a limitation on the present disclosure.

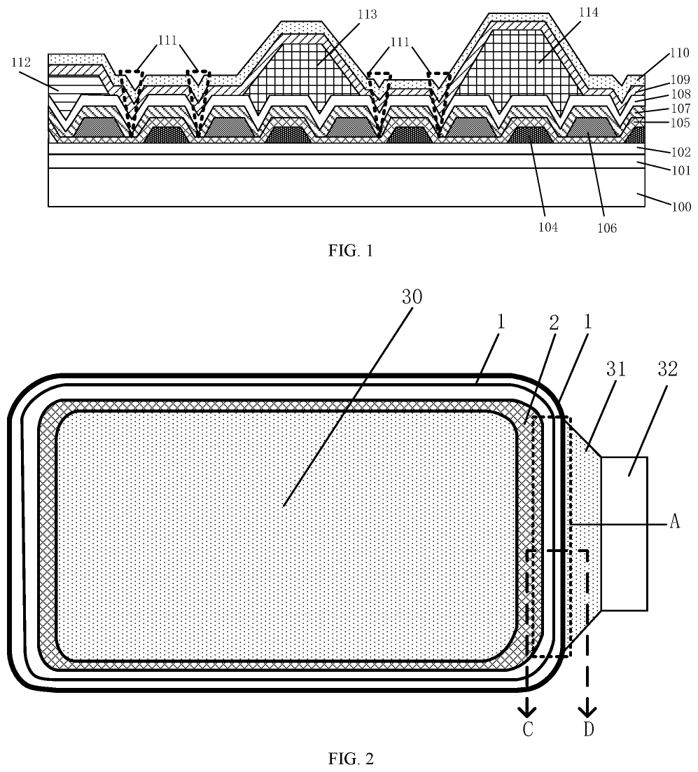

The non-displaying region of an OLED display device is usually provided with a dam region, and a blocking wall may be provided at the dam region, to solve the problem of invasion of water and oxygen caused by ink overflow during the formation of the organic packaging layer by ink-jet printing. Referring to FIG. 1, a plurality of first grid lines (Gate1) 104 and second grid lines (Gate2) 106 that are in staggered arrangement are provided on the one side of the OLED display device that is provided with the chip (IC), an ILD (inter-layer-medium layer) 107, a SD wiring 108, a planarization layer 112, a first blocking wall (dam1) 113, a second blocking wall (dam2) 114, a first inorganic layer (CVD1) 109 and a second inorganic layer (CVD2) 110 are provided over the second grid lines 106, and an inorganic insulating layer 105 is provided between the first grid lines 104 and the second grid lines 106. In FIG. 1, the OLED display device further comprises a flexible substrate 100, a Barrier layer 101 and a Buffer layer 102. Because the Gate1 and the Gate2 are arranged in stagger, slots are formed between the Gate1 and the Gate2. The subsequent film layers form depressions at the slots, and, after multiple inorganic film layers have been deposited, the depressions become narrow, to form the inversed-triangle structure 111 shown in FIG. 1. Accordingly, the first inorganic layer 109 and the second inorganic layer 110 used for packaging have a poor film-formation quality at the positions of the slots. Moreover, stress concentration easily happens there, and, during the usage of the screen, cracking easily happens, which results in invasion of water and oxygen, and causes packaging failure.

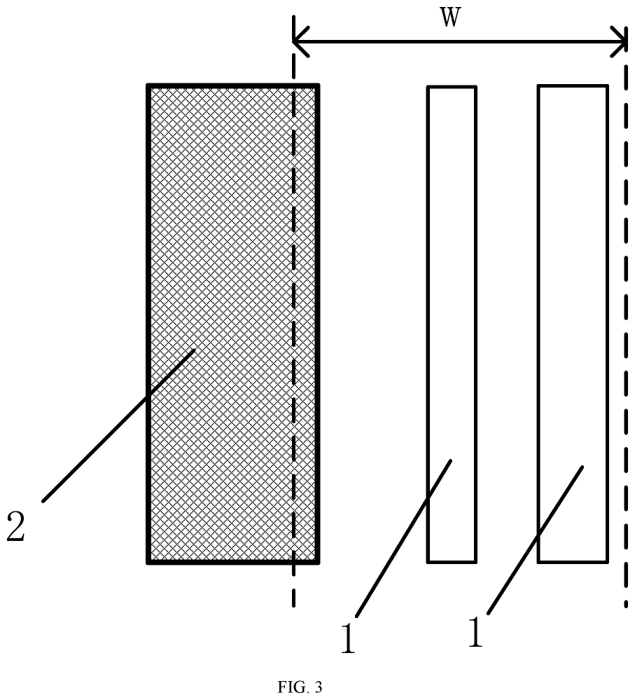

In view of the above, an embodiment of the present disclosure provides a displaying base plate. Referring to FIG. 2, the displaying base plate comprises a displaying region 30 and a non-displaying region (not shown in FIG. 2) surrounding the displaying region.

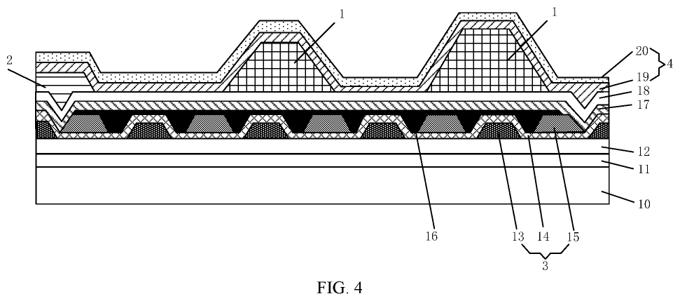

Referring to FIGS. 2 and 4, the non-displaying region comprises a substrate 10, and a first wiring unit 3, a first planarization part 2, at least one blocking wall 1, a second planarization part 16 and a packaging layer 4 that are located on the substrate 10.

Referring to FIG. 4, the first wiring unit 3 is provided with a slot (not shown in FIG. 4). The first planarization part 2 and the blocking wall 1 are provided on the one side of the first wiring unit 3 that is further away from the substrate 10. The first planarization part 2 is closer to the displaying region (not shown in FIG. 4) than the blocking wall 1, and the orthographic projection of the first planarization part 2 on the substrate 10 and the orthographic projection of the blocking wall 1 on the substrate 10 do not intersect or overlap with each other. The second planarization part 16 is located at at least the region between the first planarization part 2 and the blocking wall 1, and is configured to at least fill and level up the slot in the first wiring unit 3 that is located at the region between the first planarization part 2 and the blocking wall 1. The packaging layer 4 covers the first planarization part 2 , the blocking wall 1 and the second planarization part 16.

The first wiring unit is provided with the slot; in other words, the surface of the one side of the first wiring unit that is further away from the substrate is uneven. The particular structure of the first wiring unit is not limited herein. The first wiring unit is usually provided at the bonding region (PAD region) in the non-displaying region, i.e., the side for the provision of the chip (IC).

The second planarization part may comprise a monolayer or multilayer structure, which is not limited herein. Considering reducing the influence on the overall thickness to the largest extent, the monolayer structure is preferable. The material of the second planarization part may include organic materials such as polyimide (PI), and it may be fabricated by using a conventional process or IJP (ink-jet printing process). The second planarization part is at least located at the region between the first planarization part and the blocking wall. Certainly, the second planarization part may also be located at another region, for example, the region where the blocking wall is located or the region where the first planarization part is located, which is not particularly limited herein, and is required to be determined according to practical demands.

The second planarization part may be connected to both of the first planarization part and the blocking wall, or may also be connected to neither of the first planarization part and the blocking wall. Considering that the first planarization part and the second planarization part are often fabricated by using organic materials, and organic materials are susceptible to erosion by water and oxygen, in order to prevent water and oxygen from entering the first planarization part via the blocking wall and the second planarization part, and in turn prevent water and oxygen from passing through the first planarization part and eroding the displaying region, it is preferable that the second planarization part is connected to neither of the first planarization part and the blocking wall.

The orthographic projection of the first planarization part on the substrate refers to the projection of the first planarization part on the substrate in the direction perpendicular to the substrate. The orthographic projection of the blocking wall on the substrate refers to the projection of the blocking wall on the substrate in the direction perpendicular to the substrate. The orthographic projection of the first planarization part on the substrate and the orthographic projection of the blocking wall on the substrate do not intersect or overlap with each other; in other words, the first planarization part and the blocking wall are not connected to each other, and do not intersect or overlap with each other.

The first planarization part may also extend to the displaying region, for planarization. The first planarization part may comprise a monolayer or multilayer structure, which is not limited herein. The materials of the first planarization part and the second planarization part may be the same, or may also be different.

The blocking wall 1 may, as shown in FIG. 2, surround the entire displaying region 30, or may also surround part of the displaying region, which is not limited herein, and, in order to realize a better effect of packaging, the former is preferable. If the quantity of the blocking walls is higher, the effect of packaging is better, but the area of the non-displaying region is correspondingly increased. In order to balance the effect of packaging and the effect of narrow border frame, two blocking walls may be provided, and the two blocking walls may be arranged in the shape of concentric rings, as shown in FIG. 2. If the non-displaying region comprises a plurality of blocking walls, then the heights of the plurality of blocking walls in the direction perpendicular to the substrate may be different, or the heights of the plurality of blocking walls in the direction perpendicular to the substrate are equal, which is not limited herein. FIG. 4 illustrates by taking the case as an example in which the non-displaying region comprises two blocking walls 1, and the height in the direction perpendicular to the substrate 10 of the blocking wall 1 closer to the first planarization part 2 is less than the height in the direction perpendicular to the substrate 10 of the blocking wall 1 further away from the first planarization part 2.

The blocking wall may comprise a monolayer or multilayer structure, which is not limited herein. As an example, if the first planarization part comprises one organic layer, and the blocking wall comprises one organic layer, then the first planarization part and the blocking wall may be provided in the same layer.

Referring to FIG. 4, the packaging layer 4 may comprise a first inorganic packaging layer 19, an organic packaging layer (not shown in FIG. 4) and a second inorganic packaging layer 20 that are provided in stack, and the first inorganic packaging layer 19 is closer to the second planarization part 16 than the second inorganic packaging layer 20. The materials of the first inorganic packaging layer and the second inorganic packaging layer may include silicon oxide, silicon nitride, silicon oxynitride and so on, and they may be fabricated by using processes such as PECVD (Plasma Enhanced Chemical Vapor Deposition). The organic packaging layer may usually be formed by using an ink-jet printing process. The blocking wall can solve the problem of invasion of water and oxygen caused by ink overflow during the fabrication of the organic packaging layer.

Certainly, in the displaying base plate, the non-displaying region may further comprise an isolating layer 11 and a buffer layer 12 that are provided sequentially in stack between the substrate 10 and the first wiring unit 3. The material of the substrate may be a rigid material, such as glass, or may also be a flexible material, such as PI (polyimide), which is not limited herein. The embodiments of the present disclosure merely set forth the structures related to the inventive step, and the structures of the displaying region may refer to the related art, and are not discussed herein further.

The embodiments of the present disclosure provide a displaying base plate. The displaying base plate, in an aspect, by providing the at least one blocking wall, prevents the problem of invasion of water and oxygen caused by ink overflow during the formation of the packaging layer by ink-jet printing subsequently. In another aspect, by providing the second planarization part to fill and level up the slot in the first wiring unit that is located at the region between the first planarization part and the blocking wall, the region of the displaying base plate between the first planarization part and the blocking wall has an even surface. Therefore, after the packaging layer has been formed subsequently, the inversed-triangle structure 111 shown in FIG. 1 will not be formed, and stress concentration will not happen at the corresponding slot position, thereby greatly improving the film-formation quality of the packaging layer, and in turn preventing the problem of packaging failure caused by cracking of the displaying base plate during the usage of the screen. The displaying base plate can effectively block water and oxygen, improve the effect of packaging, and prolong the service life.

Optionally, in order to reduce the difficulty in design and simplify the structure, referring to FIG. 4, the first wiring unit 3 comprises a first wiring layer and a second wiring layer that are provided in stack, and the second wiring layer is provided on the one side of the first wiring layer that is further away from the substrate; and the first planarization part and the blocking wall are provided on the one side of the second wiring layer that is further away from the first wiring layer.

The first wiring layer comprises a plurality of first wirings 13, the second wiring layer comprises a plurality of second wirings 15, the orthographic projections of the plurality of first wirings 13 on the substrate 10 and the orthographic projections of the plurality of second wirings 15 on the substrate 10 are arranged in stagger, and slots (not shown in FIG. 4) are provided between the first wirings 13 and the second wirings 15.

The plurality of first wirings and the plurality of second wirings may be arranged in stagger in parallel, and, certainly, may also be arranged in stagger in other modes, which is not limited herein. Considering reducing the difficulty in design and saving the space, the former is preferable.

The first wirings and the second wirings may individually include grid lines, source-drain data lines and so on, which is not limited herein. If the first wirings and the second wirings individually include grid lines, then the grid lines may also extend to the displaying region, to be electrically connected to the relevant components of the displaying region.

It should be noted that, in order to prevent mutual influence between the first wiring layer and the second wiring layer, the first wiring unit 3 may further comprise an insulating layer 14. The insulating layer 14 is located between the first wiring layer and the second wiring layer, and covers the plurality of first wirings 13 of the first wiring layer. The material of the insulating layer may be an inorganic insulating material, such as silicon nitride and silicon oxide.

In addition, in the displaying base plate illustrated in FIG. 4, the second planarization part 16 is provided between the first wiring layer 3 and the second wiring layer. Certainly, the second planarization part may also be provided on the one side of the second wiring layer that is further away from the substrate, which is not limited herein. If the second planarization part is provided on the one side of the second wiring layer that is further away from the substrate, in order to prevent water and oxygen from entering the first planarization part via the blocking wall and the second planarization part, and in turn prevent water and oxygen from passing through the first planarization part and eroding the displaying region, the second planarization part is connected to neither of the first planarization part and the blocking wall.

Optionally, in order to prevent water and oxygen from entering the first planarization part via the blocking wall and the second planarization part, and in turn prevent water and oxygen from passing through the first planarization part and eroding the displaying region, the second planarization part is connected to neither of the first planarization part and the blocking wall.

Optionally, the orthographic projection of the second planarization part on the substrate and the orthographic projection of the first planarization part on the substrate partially overlap. Accordingly, the second planarization part is not only located at the region between the first planarization part and the blocking wall, but also part of it may extend to the region where the first planarization part is located, whereby the slot located at the overlapping region between the first planarization part and the second planarization part is also filled and leveled up, which facilitates to ensure that the region of the displaying base plate between the first planarization part and the blocking wall has an even surface.

Optionally, the non-displaying region comprises a plurality of blocking walls, and the second planarization part is further configured to fill and level up the slot in the first wiring unit that is located at the region located between two neighboring blocking walls, thereby preventing the packaging layer from forming an inversed-triangle structure between the two blocking walls, further improving the film-formation quality of the packaging layer, and further improving the effect of packaging.

Optionally, in order to simplify the process and reduce the cost, the second planarization part is further configured to fill and level up the slot in the first wiring unit that is located at the region where the blocking wall is located. Accordingly, the second planarization part can be provided continuously at the region between the first planarization part and the blocking wall furthest away from the first planarization part.

Further optionally, the orthographic projections of the plurality of blocking walls on the substrate are located within the orthographic projection of the second planarization part on the substrate, thereby ensuring that the slot at the region where the plurality of blocking walls are located are filled and leveled up by the second planarization part. FIG. 3 is an enlarged view of the region A defined by the dotted line in FIG. 2. Referring to FIG. 3, the width w of the second planarization part may range from 120 μm to 200 μm. Certainly, the particular width of the second planarization part may be determined according to the size of the displaying base plate.

Optionally, the non-displaying region further comprises a second wiring unit, the second wiring unit is provided on the one side of the second planarization part that is further away from the substrate, and the first planarization part and the blocking wall are provided on the one side of the second wiring unit that is further away from the substrate.

The second wiring unit may comprise a plurality of third wirings that are arranged in parallel. Referring to FIG. 4, the orthographic projections of the third wirings 18 on the substrate 10 and the orthographic projections of the plurality of second wirings 15 on the substrate 10 intersect. The angle of the intersection is not limited herein, and may be 20°, 40°, 60°, 80° and so on.

The third wirings may include grid lines, source-drain data lines and so on, which is not limited herein. If the first wirings and the second wirings individually include grid lines, then the third wirings may include source-drain data lines, and the source-drain data lines may also extend to the displaying region, to be electrically connected to the relevant components of the displaying region.

The second wiring unit is provided on the one side of the second planarization part that is further away from the substrate, and thus can isolate the second planarization part from individually the first planarization part and the blocking wall, thereby preventing the second planarization part from being connected to the first planarization part and the blocking wall, and at the same time reducing the influence on the existing structure to the largest extent.

Optionally, in order to protect the first wiring unit and the second wiring unit, referring to FIG. 4, the non-displaying region further comprises an inter-layer-medium layer 17, and the inter-layer-medium layer 17 is located between the second wiring unit and the second planarization part 16. Certainly, the inter-layer-medium layer may also extend to and cover the part of the first wiring unit that is not filled and leveled up by the second planarization part, to better protect the first wiring unit.

Optionally, Referring to FIG. 2, the blocking wall 1 surrounds the displaying region 30, and the packaging layer extends over and covers the displaying region. The non-displaying region further comprises a bonding region 32, and the region A where the second planarization part is located and the bonding region 32 are located on the same one side of the displaying region 30, to facilitate to bond the electric circuit and save the space.

The bonding region (also referred to as a PAD region) is used to provide circuit components such as the chip and the driving circuit. Certainly, referring to FIG. 2, the non-displaying region may further comprise a fanout region (also referred to as a Fanout region) 31 between the displaying region 30 and the bonding region 32, and the fanout region may be used to collect the wirings (for example, the first wirings, the second wirings, the third wirings and so on).

Referring to FIGS. 2 and 3, the region A where the second planarization part is located may be located between the displaying region 30 and the bonding region 32. Optionally, the non-displaying region further comprises the fanout region 31, and accordingly the region A where the second planarization part is located may be located between the displaying region 30 and the fanout region 31, and partially overlaps with the fanout region 31.

It should be noted that the first planarization part 2 may, as shown in FIG. 2, surround the displaying region 30, which is not limited herein.

An embodiment of the present disclosure further provides a display panel, wherein the display panel comprises the displaying base plate stated above.

The display panel may be a flexible display panel (also referred to as a flexible screen), and may also be a rigid display panel (i.e., a display panel that cannot be bent), which is not limited herein.

The display panel may be an OLED (Organic Light Emitting Diode) display panel, and may also be a Micro LED micro-display panel or Mini LED micro-display panel, and any products or components having a displaying function that comprise the display panel, such as a television set, a digital camera, a mobile phone and a tablet personal computer. The display panel can effectively block water and oxygen, and has the advantages of a good effect of packaging and a long service life.

The above are merely particular embodiments of the present disclosure, and the protection scope of the present disclosure is not limited thereto. All of the variations or substitutions that a person skilled in the art can easily envisage within the technical scope disclosed by the present disclosure should fall within the protection scope of the present disclosure. Therefore, the protection scope of the present disclosure should be subject to the protection scope of the claims.

1. A displaying base plate, wherein the displaying base plate comprises a displaying region and a non-displaying region surrounding the displaying region;
the non-displaying region comprises a substrate, and a first wiring unit, a first planarization part, at least one blocking wall, a second planarization part and a packaging layer located on the substrate;
the first wiring unit is provided with a slot;
the first planarization part and the blocking wall are provided on one side of the first wiring unit further away from the substrate;
the first planarization part is closer to the displaying region than the blocking wall, and an orthographic projection of the first planarization part on the substrate and an orthographic projection of the blocking wall on the substrate do not intersect or overlap with each other;
the second planarization part is at least located at a region between the first planarization part and the blocking wall, and is configured to at least fill and level up the slot in the first wiring unit that is located at the region between the first planarization part and the blocking wall; and
the packaging layer covers the first planarization part, the blocking wall and the second planarization part.

2. The displaying base plate according to claim 1, wherein the first wiring unit comprises a first wiring layer and a second wiring layer, the first wiring layer and the second wiring layer are provided in stack, and the second wiring layer is provided on one side of the first wiring layer further away from the substrate;
the first planarization part and the blocking wall are provided on one side of the second wiring layer further away from the first wiring layer; and
the first wiring layer comprises a plurality of first wirings, the second wiring layer comprises a plurality of second wirings, orthographic projections of the plurality of first wirings on the substrate and orthographic projections of the plurality of second wirings on the substrate are arranged in stagger, and slots are provided between the first wirings and the second wirings.

3. The displaying base plate according to claim 2, wherein the first wiring unit further comprises an insulating layer, the insulating layer is located between the first wiring layer and the second wiring layer, and the insulating layer covers the plurality of first wirings.

4. The displaying base plate according to claim 1, wherein the second planarization part is not connected to the first planarization part and the blocking wall.

5. The displaying base plate according to claim 1, wherein an orthographic projection of the second planarization part on the substrate and the orthographic projection of the first planarization part on the substrate partially overlap.

6. The displaying base plate according to claim 1, wherein the non-displaying region comprises a plurality of the blocking walls, and the second planarization part is further configured to fill and level up the slot in the first wiring unit that is located at the region located between two neighboring instances of the blocking walls.

7. The displaying base plate according to claim 6, wherein the second planarization part is further configured to fill and level up the slot in the first wiring unit located at the region where the blocking wall is located.

8. The displaying base plate according to claim 7, wherein orthographic projections of the plurality of blocking walls on the substrate are located within an orthographic projection of the second planarization part on the substrate.

9. The displaying base plate according to claim 8, wherein the width of the second planarization part ranges from 120 μm to 200 μm.

10. The displaying base plate according to claim 7, wherein the non-displaying region further comprises a second wiring unit, the second wiring unit is provided on one side of the second planarization part further away from the substrate, and the first planarization part and the blocking wall are provided on one side of the second wiring unit further away from the substrate.

11. The displaying base plate according to claim 10, wherein the first wiring unit comprises a second wiring layer, and the second wiring layer comprises a plurality of second wirings; and
the second wiring unit comprises a plurality of third wirings arranged in parallel, the orthographic projections of the third wirings on the substrate and the orthographic projections of the plurality of second wirings on the substrate intersect.

12. The displaying base plate according to claim 10, wherein the non-displaying region further comprises an inter-layer-medium layer, and the inter-layer-medium layer is located between the second wiring unit and the second planarization part.

13. The displaying base plate according to claim 1, wherein the blocking wall surrounds the displaying region, and the packaging layer extends over and covers the displaying region; and
the non-displaying region further comprises a bonding region, and a region where the second planarization part is located and the bonding region are located on a same side of the displaying region.

14. The displaying base plate according to claim 13, wherein the non-displaying region further comprises a fanout region, the region where the second planarization part is located is located between the displaying region and the fanout region, and partially overlaps with the fanout region.

15. The displaying base plate according to claim 1, wherein the packaging layer comprises a first inorganic packaging layer, an organic packaging layer and a second inorganic packaging layer provided in stack; and
the first inorganic packaging layer is located at one side of the second inorganic packaging layer closer to the second planarization part.

16. The displaying base plate according to claim 1, wherein the non-displaying region comprises an isolating layer and a buffer layer, and the isolating layer and the buffer layer are provided sequentially in stack between the substrate and the first wiring unit.

17. A display panel, wherein the display panel comprises the displaying base plate according to claim 1.

18. The display panel according to claim 17, wherein the first wiring unit comprises a first wiring layer and a second wiring layer, the first wiring layer and the second wiring layer are provided in stack, and the second wiring layer is provided on one side of the first wiring layer further away from the substrate;
the first planarization part and the blocking wall are provided on one side of the second wiring layer further away from the first wiring layer; and
the first wiring layer comprises a plurality of first wirings, the second wiring layer comprises a plurality of second wirings, orthographic projections of the plurality of first wirings on the substrate and orthographic projections of the plurality of second wirings on the substrate are arranged in stagger, and slots are provided between the first wirings and the second wirings.

19. The display panel according to claim 17, wherein the second planarization part is not connected to the first planarization part and the blocking wall.

20. The display panel according to claim 17, wherein an orthographic projection of the second planarization part on the substrate and the orthographic projection of the first planarization part on the substrate partially overlap.
